(19) United States
(12) Patent Application Publication
(10) Pub. No.: US 2024/0109421 A1
(43) Pub. Date: Apr. 4, 2024

(54) BATTERY MEASUREMENT APPARATUS AND BATTERY MEASUREMENT METHOD

(71) Applicant: DENSO CORPORATION, Kariya-city (JP)

(72) Inventors: Masaaki KITAGAWA, Kariya-city (JP); Isao ISHIBE, Kariya-city (JP)

(73) Assignee: DENSO CORPORATION, Kariya-city (JP)

(21) Appl. No.: 18/541,871

(22) Filed: Dec. 15, 2023

Related U.S. Application Data
(63) Continuation of application No. PCT/JP2022/021328, filed on May 25, 2022.

(30) Foreign Application Priority Data
Jun. 15, 2021 (JP) 2021-099707

(51) Int. Cl. B60L 3/00; B60L 58/12; B60L 58/16; B60L 58/18; G01R 31/387; G01R 31/389; G01R 31/392; G01R 31/396

(52) U.S. Cl. CPC B60L 3/0046; B60L 58/12; B60L 58/16; B60L 58/18; G01R 31/387; G01R 31/389; G01R 31/392; G01R 31/396

(57) ABSTRACT

A battery measurement apparatus connected to a battery module in which a plurality of storage batteries are combined, includes: a measurement unit that measures a battery state of at least each of the storage batteries; and a determination unit that determines whether replacement of any one of the storage batteries has occurred based on the battery state. The determination unit determines that replacement of a storage battery has occurred in the case where a parameter indicating the battery state of any one of the storage batteries that constitute the battery module is determined to be out of a predetermined range and a parameter indicating the battery state of other storage batteries or other battery modules are also determined to be out of a predetermined range.

### CROSS-REFERENCE OF RELATED APPLICATION

This application is the U.S. bypass application of International Application No. PCT/JP2022/021328 filed on May 25, 2022, which designated the U.S. and claims priority to Japanese Patent Application No. 2021-099707, filed Jun. 15, 2021, the contents of which is incorporated herein by reference.

### BACKGROUND

### Technical Field

The present disclosure relates to a battery measurement apparatus and a battery measurement method capable of determining a replacement of a storage battery.

### Description of the Related Art

Conventionally, a technique is known in which information about a storage battery is acquired by a wireless communication using an electronic tag such as RFID attached to the storage battery. The storage battery is managed based on the information about the storage battery acquired from the tag. For example, a configuration is considered, in accordance with the information about the storage battery acquired from the tag, to detect a mis-replacement of the storage battery, thereby avoiding such mis-replacement of the storage battery.

### SUMMARY

The present disclosure provides a battery measurement apparatus connected to a battery module in which a plurality of storage batteries are combined including: a measurement unit that measures a battery state of at least each of the storage batteries; and a determination unit that determines whether replacement of any one of the storage batteries has occurred based on the battery state. The determination unit determines that a replacement of the storage battery has occurred in the case where a parameter indicating the battery state of any one of the storage batteries that constitute the battery module is determined to be out of a predetermined range and a parameter indicating the battery state of other storage batteries or other battery modules are also determined to be out of a predetermined range.

### BRIEF DESCRIPTION OF THE DRAWINGS

The above-described objects and other objects, features and advantages of the present disclosure will be clarified further by the following detailed description with reference to the accompanying drawings. The drawings are:

FIG. 1 is an overall configuration of a power source system;

FIG. 2 is a block diagram showing a configuration of a battery measurement apparatus;

FIG. 3 is a flowchart showing a replacement determination process;

FIG. 4 is a block diagram showing a battery measurement apparatus according to a second embodiment;

FIG. 5 is a flowchart showing a detection process according to the second embodiment; and

FIG. 6 is a flowchart showing a notification process according to a third embodiment.

### DETAILED DESCRIPTION OF THE PREFERRED EMBODIMENTS

As a related art, European patent application laid-open publication number 3614483 discloses a technique in which information about a storage battery is acquired by a wireless communication using an electronic tag such as RFID attached to the storage battery. The storage battery is managed based on the information about the storage battery acquired from the tag. For example, a configuration is considered, in accordance with the information about the storage battery acquired from the tag, to detect a mis-replacement of the storage battery, thereby avoiding such mis-replacement of the storage battery.

The ID tag such as an electronic tag is exchangeable. In this respect, in the case where incorrect replacement is applied to the storage battery, since the ID tag is also replaced, this incorrect replacement is difficult to be completely avoided.

### First Embodiment

Hereinafter, with reference to the drawings, a first embodiment will be described in which a battery measurement apparatus is adapted for a power source system of a vehicle (e.g. hybrid vehicle or an electric vehicle).

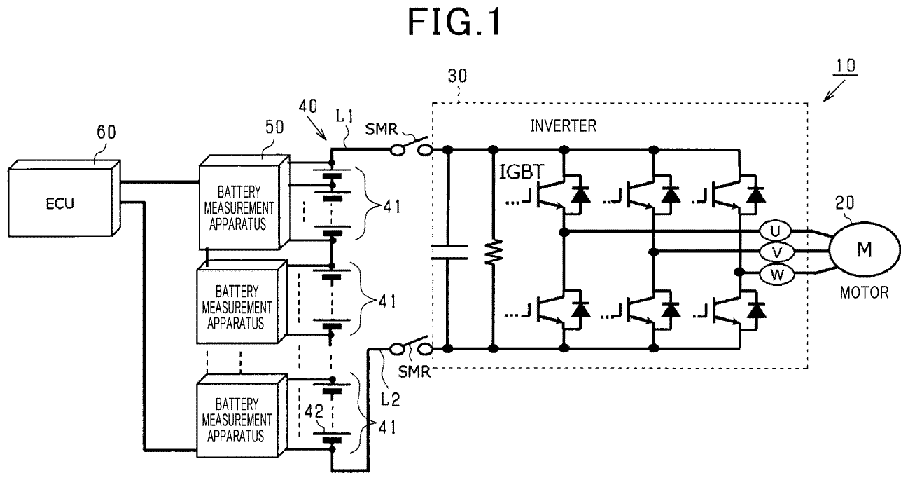

As shown in FIG. 1, the power source system 10 is provided with a motor 20 as a rotary electric machine, an inverter 30 as a power converter causing a three-phase current to flow through the motor 20, a battery module 40 capable of being charged or discharged, a battery measurement apparatus 50 that measures a state of the battery module 40 and an ECU 60 that controls the motor 20.

The motor 20 serves as an on-vehicle main power source, capable of transmitting power to driving wheels (not shown). According to the present embodiment, as the motor 20, a three-phase permanent magnet synchronous motor is used. The inverter 30 is configured of a full-bridge circuit having upper and lower arm circuits of which the number of circuits is the same as the number of phases. The energization current at respective windings are adjusted when turning the switches (semiconductor switching elements) provided at the respective arms to be ON and OFF.

The inverter 30 includes an inverter control unit (not shown) which performs an energization control by turning the respective switches in the inverter 30 to be ON and OFF based on various detection information of the motor 20, and requirements of a power running drive and a power generation. Thus, the inverter control apparatus supplies power to the motor 20 via the inverter 30 from the battery module 40, thereby causing the motor to perform power running operation. Also, the inverter control apparatus causes the motor 20 to generate power based on the motive force from the driving wheels, supplies the power in which the generated power is converted with the inverter 30 to the battery module 40, thereby charging the battery module 40.

The battery module 40 is electrically connected to the motor 20 via the inverter 30. The battery module 40 has a terminal voltage which is several hundreds of volts for example, and is configured of a plurality of battery modules 41 connected in series. The battery module 41 is configured of a plurality of battery cells 42 connected in series. As the battery cell 42, for example, a lithium-ion storage battery or a nickel-hydrate storage battery can be utilized. Each battery cell 42 is configured as a storage battery having an electrolyte and a plurality of electrodes. For each battery cell 42, an ID (identification number) is provided thereto for identifying respective battery cells 42. Similarly, IDs are added to the battery module 31 and the battery module 40.

As shown in FIG. 1, a positive electrode side terminal of an electrical load such as an inverter 30 is connected to a positive electrode side power source path L1 which is connected to the positive electrode side power source terminal of the battery module 40. Similarly, a negative electrode side terminal of an electrical load such as an inverter 30 is connected to a negative electrode side power source path L2 which is connected to the negative electrode side power source terminal of the battery module 40. For the positive electrode side power source path L1 and the negative electrode side power source path L2, a relay switch SMR (system main relay switch) is provided for each of the power source path L1 and the power source path L2. With these relay switches SMR, both power source paths L1 and L2 are configured to be switches between conduction and cutoff.

The battery measurement apparatus 50 is configured to measure a state of charge (SOC) of respective battery cells 42 and a state of deterioration (SOH). The battery measurement apparatus 50 is provided with a microcomputer composed of a CPU and various memory units, various sensors, circuits and communication units. In the first embodiment, the battery measurement apparatus 50 is provided for each battery module 41. The battery measurement apparatus 50 is provided for each battery module 41. The battery measurement apparatus 50 is connected to the ECU 60 and outputs the state of the respective battery cells 42. A configuration of the battery measurement apparatus 50 will be described later.

The ECU 60 outputs requests of a power running drive and a power generation to the inverter control apparatus based on the various information. The various information includes operation information of the accelerator and the brake, a vehicle speed, a state of the battery module 40.

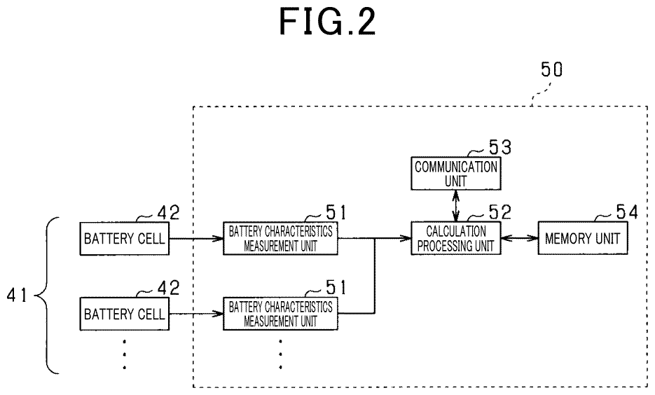

Next, the battery measurement apparatus 50 will be described in detail. As shown in FIG. 2, the battery measurement apparatus 50 is provided with a battery characteristics measurement unit 51, a calculation processing unit 52, a communication unit 53 and a memory unit 54. Note that the battery measurement apparatus 50 executes a program stored in the memory unit 54 of the battery measurement apparatus 50, thereby accomplishing various control functions. The various functions may be accomplished by electronic circuitry as hardware or may be accomplished by both the hardware and the software.

The battery characteristics measurement unit 51 is provided for each of the respective battery cells 42 which constitute the battery module 41. The battery characteristics measurement unit 51 corresponds to a measurement unit that measures the battery state of the battery cell 42. The battery characteristics measurement unit 51 is configured to be capable of measuring voltage of the battery cell 42, the internal impedance, the state of charge (SOC) and the deterioration state (SOH), as the parameters indicating the battery state of the battery to be measured. The battery characteristics measurement unit 51 is connected to the calculation processing unit 52 and configured to output the measured various parameters.

The calculation processing unit 52 performs a process for storing various parameters of the battery cell 42 transmitted from the battery characteristics measurement unit 51 into the memory unit 54 and a process for notifying the various parameters to an external unit such as the ECU 60 of via the communication unit 53. Further, the calculation unit 52 determines whether a failure has occurred on the battery cell 42 based on the various parameters of the battery cell 42 and notifies occurrence of failure to the ECU 60 if determined that failure has occurred.

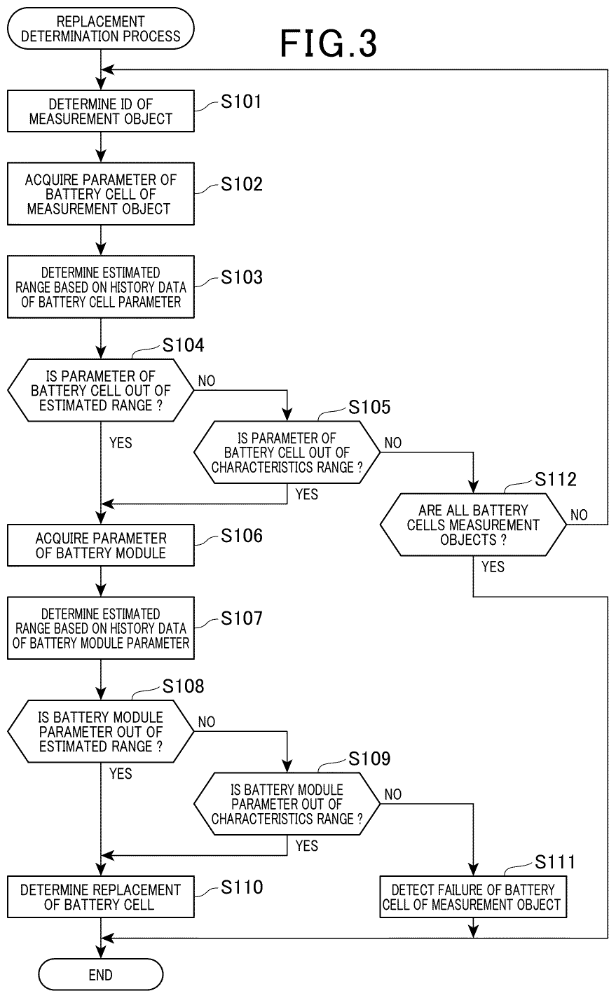

Further, the calculation processing unit 52 functions as a determination unit that determines whether the battery cell 42 has been replaced based on the battery state. With reference to FIG. 3, a replacement determination process will be described. The replacement determination process is executed by the calculation processing unit 52 at a predetermines timing. For example, the replacement determination process is executed when the vehicle starts or stops.

The calculation processing unit 52 determines the ID of a battery cell 42 to be measured (monitoring object) in the battery module 41 (step S101). The battery cell 42 to be measured is determined in accordance with a predetermined order.

Next, the calculation processing unit 52 acquires various parameters of the battery cell 42 to be measured from the battery characteristics measurement unit 51 (step S102). According to the present embodiment, the voltage, the internal impedance, SOC and SOH of the battery cell 42 as the parameter of the battery cell 42 is measured by the battery characteristics measurement unit 51 and these parameters are acquired from the battery characteristics measurement unit 51. Note that the battery characteristics measurement unit does not necessarily measure and calculate of all of these parameters, but the calculation processing unit 52 may calculate a part of parameters (SOC, SOH and the like) based on the measurement information (voltage value and current value) acquired by the battery characteristics measurement unit 51. In this case, the calculation processing unit 52 serves as a part of the measurement unit.

Further, the calculation processing unit 52 acquires respective history data of the parameters of the battery cell 42 to be measured from the memory unit 54, and determines each estimated range estimated based on the history data of the respective parameters (step S103). Specifically, the process identifies respective parameter values previously acquired from the history data of the respective parameters and determines, based on the respective parameter values and the elapsed time from a time when the respective parameter values are previously acquired, possible estimated range where the respective parameters are present within this range. The estimated range may be determined in the following manner. By experiment or a simulation and the like, a map or an equation showing a relationship between an elapsed time and the respective parameters may be identified and the calculation processing unit 52 may determine the estimated range referring to the map or the like stored in the memory unit 54.

Moreover, an approximated curve of the respective parameters may be calculated from the history of the respective parameters, and the estimated range may be determined using the elapsed time from the previous acquired time and the approximated curve. When the estimated range is determined, a margin value may preferably be set for the estimated range considering an amount of possible error.

Then, the calculation processing unit 52 determines whether each of the respective current parameters of the battery cell 42 acquired at step S102 is out of the estimated range (step S104). In the case where any one of the parameters is out of estimated range, the calculation processing unit 52 makes a positive determination at step S104. On the other hand, when all of the parameters are within the estimated range, the calculation processing unit 52 makes a negative determination at step S104.

When the determination result at step S104 is negative, the calculation processing unit 52 determines whether each of the acquired respective parameters of the battery cells 42 is out of allowable characteristic range (step S105). The characteristics range refers to a range where the respective parameter values are within this range, and a range satisfying the spec of the battery cell 42 (available range). The characteristics range can be identified depending on the characteristics of the battery cell 42. In this respect, characteristics of the voltage, characteristic range of the internal impedance, the characteristics range of the SOC and the characteristics of the SOH are defined depending on the type, size, capacity of the electrolyte and the electrode constituting the battery cell 42. These characteristics ranges can be identified by experiment, simulation and the like and are stored in the memory unit 54.

When any one of parameters is out of the allowable characteristics range, the calculation processing unit 52 makes a positive determination at step S105. On the other hand, all of the parameters are within the characteristics range, the calculation processing unit 52 makes a negative determination at step S105.

When the determination result at step S104 or step S105 is positive, the calculation processing unit 52 acquires various parameters of the battery module 41 (step S106). According to the present embodiment, as the parameters of the battery module 41, the voltage, the internal impedance, SOC and SOH of the battery module 41 are acquired. The calculation processing unit 52 may acquire respective parameters of the battery cell 42 that constitutes the battery module 41 and calculate, based on these parameters, the parameters of the battery module 41. Alternatively, the battery characteristics measurement unit 51 that measures respective parameters of the battery module 41 may be additionally provided and the calculation processing unit 52 may acquire the parameters of the battery module 41 from the battery characteristics measurement unit 51.

Further, the calculation processing unit 52 acquires the history data of the respective parameters of the battery module 41 to be measured from the memory unit 54 and determines the estimated range estimated based on the history data of the respective parameters (step S107). Then, the calculation processing unit 52 determines whether each of the respective current parameters of the battery module 41 acquired at step S106 is out of estimated range (step S108). Sincer the processes at step S107 and S108 are similar to those at steps S103 and S104, detailed explanation will be omitted.

When the determination result at step S108 is negative, the calculation processing unit 52 determines whether each of the acquired respective parameters of the battery module 41 is out of the allowable characteristics range of the respective parameters (step S109). Since the process at step S109 is similar to that of step S105, detailed explanation thereof will be omitted.

When the determination result at step S108 or step S109 is positive, the calculation processing unit 52 determines that the battery cell 42 has been replaced and notifies the ECU 60 of the determination result (step S110). On the other hand, when the determination result at step S109 is negative, the calculation processing unit 52 detects a failure of the battery cell 42 to be measured and notifies the ECU 60 of the detected failure (step S111). After performing the processes at steps S110 and S111, the process terminates the replacement determination process.

Also, if the determination result at step S105 is negative, the calculation processing unit 52 determines whether all of the battery cells 42 constituting the battery module 41 are measured as the measurement objects. When the determination result is negative, the calculation processing unit 52 proceeds to step S101. On the other hand, if the determination result at step S112 is positive, the calculation processing unit 52 determines that no replacement of the battery cell 42 has occurred and terminates the replacement determination process.

According to the first embodiment, the processes at steps S103 to S105 determine whether parameters of the battery cell 42 to be measured are out of the predetermined range. Similarly, the processes at steps S107 to S109 determine whether parameters of the battery module 41 are out of the predetermined range. Also, the battery measurement apparatus 50 executes the replacement determination process, thereby performing the battery measurement process. Note that process at step S102 corresponds to a measurement step that measures the battery state of the battery cell 42 and process at step S106 corresponds to a measurement step that measures the battery module 41. Also, processes at steps S103 to S105 and S107 to S110 correspond to a determination step that determines whether the battery cell 42 has been replaced.

According to the above-described embodiment, the following significant effects and advantages can be obtained.

In the case where a parameter of any one of the battery cell 42 shows an abnormal value, it is difficult to determine which one of a degradation of the battery cell 42, a failure, a submersion and a replacement has caused a significant change in the parameter value. On the other hand, in the case where the battery cell 42 has been replaced, usually, the battery module 41 has been replaced together with a plurality of battery cells 41 included therein.

In this respect, the calculation processing unit 52 determines that the battery cell 42 has been replaced when determined that the parameter of any one of battery cell 42 that constitutes the battery module 41 is out of a predetermined range and the parameter of the battery module 41 is also out of a predetermined range. Thus, not only the parameter of a single battery cell but also the parameter of the battery module 41 are taken into consideration, and the replacement of the battery cell 42 can be appropriately determined.

Further, comparing a tag attached to the battery cell 42 and the like, the parameter is difficult to be changed. Hence, even when incorrect replacement occurs, the replacement can be appropriately determined in accordance with the parameter of the battery cell 42 or the parameter of the battery module 41.

Since a value of the complex impedance (internal impedance) of the battery cell 42 varies depending on a deterioration state of the battery cell 42, the complex impedance is unlikely to be intentionally changed compared to the voltage or the SOC. The battery characteristics measurement unit 51 measures at least a plurality of parameters including an internal impedance and the calculation processing unit 52 determines, based on the plurality of parameters including the internal impedance whether the battery cell 42 has been replaced. Hence, compared to a case of determining based on parameters other than the internal impedance, the determination accuracy can be improved. Further, since the determination is made based on a plurality of parameters, compared to a case of determining based on a single parameter, the determination accuracy can be improved.

In the case where all of the acquired parameters are outlier values (jumped value) against the history value, compared to a case of erroneous measurement, the battery cell 42 is most likely to be replaced. In this respect, in the case where the acquired respective parameter values are out of the estimated range which is estimated based on the history data of the respective parameters, the calculation processing unit 52 determines that the parameters are out of predetermined range (failure is present). Thus, compared to a case where it is determined whether the parameter has a failure without taking the history data into consideration, a replacement can be accurately determined.

Further, in the case where each of the acquired respective parameter values is out of allowable characteristics range of the respective parameters, the calculation processing unit 52 determines that the parameters are out of predetermined range (failure is present). Since the allowable characteristics range can be identified depending on the characteristics of the battery cell 42, a case where the battery cell 42 has been replaced to one having different electrolyte and different electrodes can readily be detected.

Further, according to the present embodiment, it is determined that the battery cell 42 is replaced when the acquired respective parameters are out of the estimated range or the characteristics range. Hence, compared to a case of determining with only one of the estimated range and the characteristics range, replacement of the battery cell 42 can be more appropriately detected.

Further, according to the first embodiment, it is determined whether the acquired respective parameters are out of the estimated range of the characteristics range also for the battery module 41. Hence, compared to a case of determining with only one of the estimated range and the characteristics range, replacement of the battery cell 42 can be more appropriately detected.

### Second Embodiment

The above-described embodiment may be modified similar to the subsequent second embodiment. Hereinafter, in the second embodiment, configurations different from those in the above-described embodiment will mainly be described. In the second embodiment, as a basic configuration, a power source system 10 of the first embodiment will be described as an example.

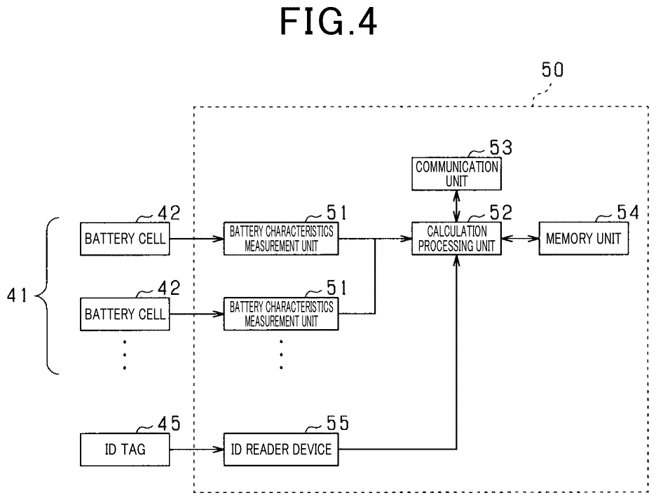

According to the second embodiment, for each battery module 41, an ID tag 45 is provided attached thereto as an identification tag capable of identifying the ID of each battery module 41. Further, as shown in FIG. 4, the battery measurement apparatus 50 is provided with an ID reader device 55 for reading the ID of the battery module 41 from the ID tag 45. The ID reader device 55 reads the IDs of the battery modules 41 from the ID tags 45 via wireless communication for example.

With reference to FIG. 5, a detection process according to the second embodiment will be described. The contents of processes of the replacement determination process at steps S101 to S111 according to the second embodiment are similar to those in the first embodiment. Note that illustration of the replacement determination process at steps S101 to S111 according to the second embodiment is omitted to simplify the drawings.

When the determination result at step S109 is negative, the calculation processing unit 52 acquires the ID of the battery module 41 (step S201) via the ID reader device 55. Then, the calculation processing unit 52 compares the acquired ID of the battery module 41 with an ID of the battery module 41 stored in advance in the memory unit 54 and determines whether they are matched (step S202).

When the determination result is negative, the calculation processing unit 52 proceeds to step S110 and determines that the battery cell 42 has been replaced and notifies the ECU 60 of the determination result. On the other hand, when the determination result at step S202 is positive, the calculation processing unit 52 proceeds to step S111, detects a failure of the battery cell 42 to be measured and notifies the ECU 60 of the determination result. Then, the process terminates the replacement determination process.

According to the above-described embodiments, the following significant effects and advantages can be obtained.

Since the calculation processing unit 52 compares the acquired ID of the battery module 41 with an ID of the battery module 41 stored in advance in the memory unit 54, the replacement can be accurately detected.

### Third Embodiment

The configuration of the first embodiment may be modified as a third embodiment as follows. Hereinafter, according to the third embodiment, in the third embodiment, configurations different from those in the above-described embodiment will mainly be described. In the third embodiment, as a basic configuration, a power source system 10 of the first embodiment will be described as an example.

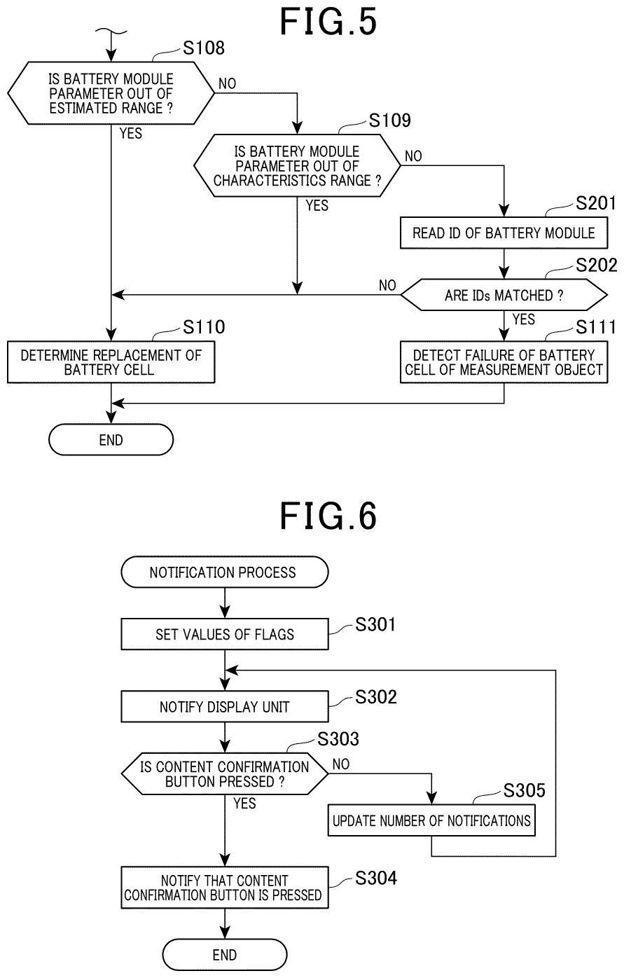

The calculation processing unit 52 executes a notification process shown in FIG. 6 when the replacement determination process detects a replacement of the battery cell 42. When the notification process is executed, the calculation processing unit 52 sends a notification to the ECU 60 for setting a value of a battery deterioration verification flag used for prompting a verification of a deterioration of the battery and a value of an error flag indicating that the battery cell 42 has been replaced (step S301).

Next, the calculation processing unit 52 causes a display unit (display or lamp) as a notification unit provided in the vehicle to notify passengers of the vehicle that the battery module 41 may be replaced.

The calculation processing unit 52 determine whether a content confirmation button indicating that the notification is confirmed is pressed (step S303) within a prescribed period from a notification start timing. When the determination result is positive, the calculation processing unit 52 notifies the ECU 60 of the determination result (step S304). On the other hand, when the determination result is negative, the calculation processing unit 52 updates the number of notifications stored in the memory unit 54 (step S305) and execute the step S302 after a predetermined period elapses.

According to the above-described embodiments, the following significant effects and advantages can be obtained.

Since the notifications are repeatedly issued until the content confirmation button is pressed, passengers on the vehicle can be reliably notified. Further, since the number of notifications is memorized, handling by the dealer can be changed depending on the number of notifications.

### Modification Examples

Hereinafter, modification examples in which a part of the configuration in the above-described embodiments is modified will be described.

In the above-described embodiments, the parameter is not limited to voltage, internal impedance, SOC and SOH. The type of parameter, and the number of parameters of the battery cell 42 may be arbitrarily changed. Moreover, the parameter may include an internal pressure of the battery cell 42, an ultra-sonic wave response and a reaction heat of the battery cell 42. Note that the parameter may preferably include an internal impedance.

In the above-described embodiments, the battery characteristics measurement unit 51 is included in the battery measurement apparatus 50. Alternatively, a measurement apparatus provided outside the vehicle may measure battery parameters and the calculation processing unit 52 of the battery measurement apparatus 50 may receive the battery parameters. In this case, the measurement apparatus provided outside the vehicle corresponds to measurement unit.

In the above-described embodiments, the calculation processing unit 52 may only determine whether the acquired parameters are out of the characteristics range (steps S105, S109) without determining whether the acquired parameters are out of the estimated range (steps S103, S104, S107, S108). Conversely, the calculation processing unit 52 may only determine whether the acquired parameters are out of the estimated range (steps S103, S104, S107, S108) without determining whether the acquired parameters are out of the characteristics range (steps S105, S109).

Moreover, the calculation processing unit 52 may determine whether the parameters of the battery cell 42 are out of the estimated range (steps S103, S104). On the other hand, the calculation processing unit 52 may not determine whether the parameters of the battery module 41 are out of the estimated range (steps S107, S108). Moreover, the opposite case may be possible.

Similarly, the calculation processing unit 52 may determine whether the parameters of the battery cell 42 are out of the characteristics range (step S105). On the other hand, the calculation processing unit 52 may not determine whether the parameters of the battery module 41 are out of the characteristics range (step S109). Moreover, the opposite case may be possible.

In the above-described embodiments, the type of parameters or the number of parameters for comparatively determining may be set differently between the battery cell 42 and the battery module 41. For example, the parameters used for comparatively determining the battery cell 42 may be set to be the internal impedance and the SOC, and the parameters used for comparatively determining the battery module 41 may be set to be voltage.

In the above-described embodiments, the calculation processing unit 52 determines whether the parameters of the battery module 41 are out of the predetermined range when the parameter of the battery cell 42 to be measured are out of the predetermined range. As a modification example thereof, the calculation processing unit 52 may determine whether the parameters of other battery cells 42 that constitutes the battery module 41 are out of the predetermined range when the parameters of the battery cell 42 to be measured are out of the predetermined range. The other battery cell 42 may be any cell or a plurality of battery cells. For example, the calculation processing unit 52 may determine all of the other battery cells 42 that constitute the battery module 41 are out of the predetermined range, when the parameters of the battery cell 42 to be measured are out of the predetermined range.

Since the battery cell 42 to be measured is included in the battery module 41, the parameters (parameters determined as a failure) of the battery cell 42 to be measured influences the parameters of the battery module 41. Hence, it is possible that the parameters of the battery module 41 may be determined to be out of the predetermined range. In this respect, the calculation processing unit 52 may determine parameters based on the parameters of the battery cell 42 other than the battery cell 42 to be measured, whereby determination can be appropriately made without being influenced by the battery cell 42 to be measured.

In the above-described second embodiment, the calculation processing unit 52 determines whether the parameters of the battery module 41 are out of predetermined range when the parameters of the battery cell 42 to be measured are out of predetermined range. As a modification example of this configuration, when the parameters of the battery cell 42 to be measured are out of the predetermined range, the calculation processing unit 52 may be configured to verify the ID of the battery module 41 without performing the processes at steps S106 to S109 to determine the parameters. With this modification example, a determination can be made with a simple configuration.

According to the above-described embodiments, the battery cell 42 may be configured as a battery pack composed of a plurality of battery cells 42. In this case, the battery pack corresponds to the storage battery.

According to the above-described embodiments, the calculation processing unit 52 makes a positive determination when any one of parameters is out of estimated range, but may make a positive determination when all of the parameters are out of estimated range. Alternatively, the calculation processing unit 52 may make a positive determination when one or more parameters including the internal impedance is out of estimated range. Similarly, the calculation processing unit 52 makes a positive determination when any one of parameters is out of characteristics range, but may make a positive determination when all of the parameters are out of the characteristics range. Also, when one or more parameters including the internal impedance are out of the characteristics range, the calculation processing unit 52 may make a positive determination.

In the above-described second embodiment, the calculation processing unit 52 verifies the ID of the battery module 41, but may read the ID of the battery cell 42 to be measured and verify it. In this case, an ID tag is provided for each battery cell 42.

In the above-described third embodiment, in the case where the number of notifications is a predetermined number or larger, the vehicle may be locked disabling the operation of the vehicle.

An environmental information acquiring unit may be provided in the battery measurement apparatus 50 of the above-described embodiments to acquire an environmental information (external temperature, battery temperature, external air pressure and the like) related to an environment where the battery cell 42 is disposed. Then, the battery characteristics measurement unit 51 (or calculation processing unit 52) may correct various parameters based on the environmental information acquired by the environmental information acquiring unit. Further, the calculation processing unit 52 may determine whether the various parameters are out of the predetermined range while taking environmental information into consideration.

In the above-described embodiments, the memory unit 54 is mounted on a vehicle. However, a memory unit 54 may be externally provided outside the vehicle for storing a history of the parameters and the like which may be utilized. At this moment, the calculation processing unit 52 transmits and receives information related to the parameters via the communication unit 53.

The battery measurement apparatus 50 according to the above-described embodiments may be applied to vehicles such as REV, EV, PHV, auxiliary battery, electric airplane, electric motorcycle and electric vessel.

In the above-described second embodiment, the ID reader device 55 may be provided outside the battery measurement apparatus 50. In this case, the battery measurement apparatus 50 may acquire information acquired from the identification tag from the ID reader device 55.

In the above-described second embodiment, ID is not limited to number's format but any format data may be utilized. For example, a bar code including a two-dimensional code or a serial code composed of numbers and characters may be utilized. The ID reader device 55 may be configured as a machine which directly reads these items. Moreover, operators or the like may directly read the ID and may directly send the ID to the battery measurement apparatus 50.

In the above-described second embodiment, the ID tag 45 may be an electronic tag such as RFID. In this case, even when the ID tag 45 is disposed at a portion which is unlikely to be visually recognized (portion visually unrecognized), the ID can be read via electromagnetic waves. That is, although the ID tag is disposed inside the battery module 41 or the like, ID can be read without opening the case thereof.

The disclosure herein is not limited to the illustrated embodiments. The disclosure includes exemplary embodiments and modifications by persons skilled in the art based on the exemplary embodiments. For example, the disclosure is not limited to the components and/or element combinations indicated in the embodiments. The disclosure can be carried out in various combinations. The disclosure can have additional components that can be added to the embodiments. The disclosure includes those in which the components and/or elements of the embodiments are omitted. The disclosure includes the replacement or combination of parts and/or elements between one embodiment and another. The technical scope disclosed is not limited to the description of the embodiments. Some technical scopes disclosed are indicated by the statement of the claims and should be understood to include all modifications within the meaning and scope equivalent to the claims statement.

The control unit and method thereof disclosed in the present disclosure may be accomplished by a dedicated computer constituted of a processor and a memory programmed to execute one or more functions embodied by computer programs. Alternatively, the control unit and method thereof disclosed in the present disclosure may be accomplished by a dedicated computer provided by a processor configured of one or more dedicated hardware logic circuits. Further, the control unit and method thereof disclosed in the present disclosure may be accomplished by one or more dedicated computer where a processor and a memory programmed to execute one or more functions, and a processor configured of one or more hardware logic circuits are combined. Furthermore, the computer programs may be stored, as instruction codes executed by the computer, into a computer readable non-transitory tangible recording media.

The present disclosure has been described in accordance with the embodiments. However, the present disclosure is not limited to the embodiments and structure thereof. The present disclosure includes various modification examples and modifications within the equivalent configurations. Further, various combinations and modes and other combinations and modes including one element or more or less elements of those various combinations are within the range and technical scope of the present disclosure.

### Conclusion

The present disclosure provides a battery measurement apparatus and method capable of determining a replacement of a storage battery. According to the present disclosure, a battery measurement apparatus connected to a battery module in which a plurality of storage batteries are combined, includes: a measurement unit that measures a battery state of at least each of the storage batteries; and a determination unit that determines whether replacement of any one of the storage batteries has occurred based on the battery state. The determination unit determines that a replacement of the storage battery has occurred in the case where a parameter indicating the battery state of any one of the storage batteries that constitute the battery module is determined to be out of a predetermined range and a parameter indicating the battery state of other storage batteries or other battery modules are also determined to be out of a predetermined range.

Further, according to the present disclosure, a method for measuring a battery performed by a battery measurement apparatus connected to a battery module in which a plurality of storage batteries are combined, includes: a measuring step that measures a battery state of at least each of the storage batteries; and a determination step that determines a replacement of the storage batteries based on the battery state. The determination step determines that a replacement of the storage battery has occurred in the case where a parameter indicating the battery state of any one of the storage batteries that constitute the battery module is determined to be out of a predetermined range and a parameter indicating the battery state of other storage batteries or other battery modules are also determined to be out of a predetermined range.

According to the above-described configuration, the determination unit determines that replacement of the storage battery has occurred in the case where a parameter indicating the battery state of any one of the storage batteries that constitute the battery module is determined to be out of a predetermined range and a parameter indicating the battery state of other storage batteries or other battery modules are also determined to be out of a predetermined range. Thus, not only the parameter of a single storage battery, but also parameters of other storage batteries or the battery modules are taken into consideration. Hence, a replacement of the storage battery can be appropriately determined.

Further, comparing a tag attached to the storage battery and the like, the parameter is difficult to be changed. Therefore, a replacement is determined based on the parameters of the storage battery and the battery module, whereby incorrect replacement can readily be detected.

What is claimed is:

1. A battery measurement apparatus connected to a battery module wherein a plurality of storage batteries are combined, the battery measurement apparatus comprising:
a measurement unit that measures a battery state of at least each of the storage batteries; and
a determination unit that determines whether a replacement of any one of the storage batteries occurs based on the battery state,
wherein
the determination unit determines that the replacement of the storage battery has occurred in the case where a parameter indicating the battery state of any one of the storage batteries that constitute the battery module is determined to be out of a predetermined range and a parameter indicating the battery state of other storage batteries or other battery modules are also determined to be out of the predetermined range.

2. The battery measurement apparatus according to claim 1,
wherein
the measurement unit is configured to measure one or more parameters indicating a battery state of the storage battery and one or more parameters indicating a battery state of the battery module; and
the determination unit determines that the replacement of the storage battery has occurred in the case where a parameter of any one of storage batteries is determined to be out of a predetermined range and a parameter, among the parameters of the battery module, of which the type is different from that of the parameter of the one of storage batteries is determined to be out of the predetermined range.

3. The battery measurement apparatus according to claim 1,
wherein
the parameter indicating the battery state includes a plurality of parameters including at least an internal impedance; and
the determination unit determines, when each parameter acquired by the measurement unit is out of an estimated range estimated based on a history of each parameter, that the parameter is out of the predetermined range.

4. The battery measurement apparatus according to claim 1,
wherein
the parameter indicating the battery state includes a plurality of parameters including at least an internal impedance;
characteristics range as a range where respective parameter values are within this range is capable of being identified depending on characteristics of the storage battery; and
the determination unit determines, when each parameter acquired by the measurement unit is out of characteristics range of each parameter, that the parameter is out of the predetermined range, that the parameter is out of the predetermined range.

5. The battery measurement apparatus according to claim 1,
wherein
an identification tag capable of identifying the storage battery is applied to the storage battery;
the determination unit determines that the storage battery has been replaced in the case where the parameter is determined to be out of the predetermined range and information acquired from the identification tag indicates that the replacement of the storage battery and outputs information indicating the replacement of the storage battery.

6. The battery measurement apparatus according to claim 1,
wherein
the battery measurement apparatus is provided with an environmental information acquiring unit that acquires environmental information related to an environment where the storage battery is disposed;
the parameter is corrected based on the environmental information; and
the determination unit determines whether the parameter is out of the predetermined range while taking the environmental information into consideration.

7. The battery measurement apparatus according to claim 1,
wherein
the storage battery is mounted on a vehicle;
the battery measurement apparatus is provided with a communication unit that transmits and receives information related to the battery state; and
history data of the battery state is stored in an external memory unit.

8. The battery measurement apparatus according to claim 1,
wherein
the battery measurement apparatus is provided with a notification unit that issues, when detecting replacement of the storage battery, a notification of the replacement.

9. A method for measuring a battery performed by a battery measurement apparatus connected to a battery module in which a plurality of storage batteries are combined, the method comprising:
a measuring step that measures a battery state of at least each of the storage batteries; and
a determination step that determines the replacement of the storage batteries based on the battery state,
wherein
the determination step determines that the replacement of the storage battery has occurred in the case where a parameter indicating the battery state of any one of the storage batteries that constitute the battery module is determined to be out of a predetermined range and a parameter indicating the battery state of other storage batteries or other battery modules are also determined to be out of a predetermined range.
